(19) United States
(12) Patent Application Publication
(10) Pub. No.: US 2026/0261204 A1
(43) Pub. Date: Sep. 3, 2026

(54) POWER SYSTEM TRANSFORMER

(71) Applicant: Texas Instruments Incorporated, Dallas, TX (US)

(72) Inventors: David REUSCH, Allen, TX (US); Branko MAJMUNOVIC, Dallas, TX (US)

(73) Assignee: Texas Instruments Incorporated, Dallas, TX (US)

(21) Appl. No.: 19/066,282

(22) Filed: Feb. 28, 2025

(51) Int. Cl. H02M 3/00; H02M 3/335; H05K 1/18

(52) U.S. Cl. CPC H02M 3/003; H02M 3/335; H05K 1/18; H05K 2201/1003

(57) ABSTRACT

An apparatus includes a substrate, a core, a primary side circuit, first and second secondary side circuits, a primary winding, and first and second secondary windings. The substrate includes first, second, and third metal layers. The core is in the substrate. The primary side circuit, and the first and second secondary side circuits are on the substrate. The primary winding is in the first metal layer of the substrate. The primary winding wraps around the core and is coupled to the primary side circuit. The first secondary winding is in the second metal layer of the substrate. The first secondary winding wraps around the core and is coupled to the first secondary side circuit. The second secondary winding is in the third metal layer of the substrate. The second secondary winding wraps around the core and is coupled to the second secondary side circuit.

### BACKGROUND

Distributed power systems may convert an input voltage to a final output voltage in multiple stages. For example, an intermediate bus converter may be used as the first stage to convert 48 volts to an intermediate voltage, and a multiphase buck converter may convert the intermediate voltage to the final output voltage. The converters of such a power system use transformers to transfer energy and provide electrical isolation. The transformers account for a significant portion of the physical area and power loss in the distributed power system.

### SUMMARY

In one example, an apparatus includes a substrate, a core, a primary side circuit, first and second secondary side circuits, a primary winding, and first and second secondary windings. The substrate includes first, second, and third metal layers. The core is in the substrate. The primary side circuit, and the first and second secondary side circuits are on the substrate. The primary winding is in the first metal layer of the substrate. The primary winding wraps around the core and is coupled to the primary side circuit. The first secondary winding is in the second metal layer of the substrate. The first secondary winding wraps around the core and is coupled to the first secondary side circuit. The second secondary winding is in the third metal layer of the substrate. The second secondary winding wraps around the core and is coupled to the second secondary side circuit.

In another example, a power converter includes a substrate, a core, a primary winding, first and second secondary windings, a primary side circuit, and first and second secondary side circuits. The substrate includes first, second, and third metal layers. The core is in the substrate. The primary winding is in the first metal layer of the substrate. The primary winding wraps around the core. The first secondary winding is in the second metal layer of the substrate. The first secondary winding wraps around the core. The second secondary winding is in the third metal layer of the substrate. The second secondary winding wraps around the core. The primary side circuit includes a first and second transistors respectively coupled to a first end and a second end of the primary winding. The first secondary side circuit includes first and second rectifier circuits respectively coupled to a first end and a second end of the first secondary winding. The second secondary side circuit includes third and fourth rectifier circuits respectively coupled to a first end and a second end of the second secondary winding.

In a further example, a system includes a processor and a multiphase converter. The multiphase converter is coupled to the processor. The multiphase converter includes a substrate, a core, a primary winding, first and second secondary windings, a primary side circuit, and first and second secondary side circuits. The substrate includes first, second, and third metal layers. The core is in the substrate. The primary winding is in the first metal layer of the substrate. The primary winding wraps around the core. The first secondary winding is in the second metal layer of the substrate. The first secondary winding wraps around the core. The second secondary winding is in the third metal layer of the substrate. The second secondary winding wraps around the core. The primary side circuit includes first and second transistors respectively coupled to a first end and a second end of the primary winding. The first secondary side circuit includes first and second rectifier circuits respectively coupled to a first end and a second end of the first secondary winding. The second secondary side circuit includes third and fourth rectifier circuits respectively coupled to a first end and a second end of the second secondary winding.

### BRIEF DESCRIPTION OF THE DRAWINGS

FIG. 1 is a side view of an example system that uses an intermediate bus converter to power a load circuit.

FIG. 2 is a schematic of an example converter that includes multiple secondary cells coupled to a core.

FIG. 3 is schematic of the converter of FIG. 2 showing example primary and secondary circuitry.

FIG. 4 is a schematic of a converter including multiple core legs and multiple secondary cells coupled to each core leg.

FIG. 5 is a schematic of an example full bridge primary circuit suitable for use in the converter of FIG. 2.

FIG. 6A is a schematic of an example full bridge secondary circuit suitable for use in the converter of FIG. 2.

FIG. 6B is a schematic of an example center tap secondary circuit suitable for use in the converter of FIG. 2.

FIG. 7 is a graph of example voltage and current in the converter of FIG. 2.

FIG. 8 is top view of an example of the converter of FIG. 2.

FIGS. 9A and 9B are cross-sectional views of the example transformer of FIG. 8.

FIG. 10 is a top view of an example of the converter of FIG. 4.

FIG. 11 is a cross-sectional view of the example transformers of FIG. 10.

FIG. 12 is a top view of an example top layer of a substrate suitable for use in the converter of FIG. 10.

FIGS. 13A-13F are top views of example internal layers of a substrate suitable for use in the converter of FIG. 10.

FIG. 14 is a top view of an example converter including multiple secondary cells coupled to each core.

FIG. 15A is a cross-sectional view of an example of the converter of FIG. 4 with secondary cells provided on both sides of a substrate.

FIG. 15B is a top view of the converter of FIG. 13A.

FIG. 16 is a top view of an example layer of a substrate showing winding of a primary about multiple cores.

FIGS. 17A and 17B are top views of an example layer of a substrate showing multiple secondary cells in a multiple core leg structure.

### DETAILED DESCRIPTION

In converters of a distributed power system, such as intermediate bus converters, transformers can account for a significant portion of the physical area and power loss in the distributed power system. For example, in an intermediate bus converter, the transformers can account for about 50% of the circuit area, and about 50% of the power loss. About 30%-40% of the loss can be termination loss.

The converters described herein reduce circuit area and termination loss by including multiple secondary windings about each core of the transformer, and providing multiple secondary cells distributed around the core. Each secondary cell is coupled to one of the secondary winds. Including multiple secondary winds about each core can reduce the number of cores, and reduce circuit size, while the multiple secondary cells can reduce significantly termination loss (e.g., 33% reduction in termination loss) by reducing the current flowing through each secondary winding.

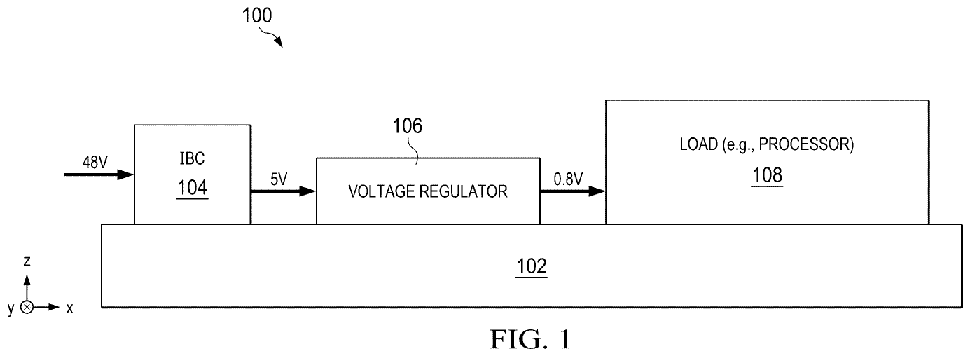

FIG. 1 is a side view of an example system 100. The system 100 includes a substrate 102, an intermediate bus converter 104, a voltage regulator 106, and load circuit 108. The intermediate bus converter 104 and the voltage regulator 106 can be a multiphase power converter. The substrate 102 can be a printed circuit board (PCB) or other substrate that provides conductors for interconnecting circuits. The intermediate bus converter 104 is a switching converter (a downconverter in FIG. 1) that converts an input voltage (e.g., 48 volts in FIG. 1) to an output voltage (5 volts in FIG. 1). The intermediate bus converter 104 has an input coupled to an input voltage terminal (not shown), via a conductor of the substrate 102, for receipt of the input voltage. The output voltage provided by the intermediate bus converter 104 is an intermediate voltage (not the final voltage needed to power the load circuit 108). The intermediate bus converter 104 has an output at which the intermediate voltage is provided.

The voltage regulator 106 is a switching converter that converts the intermediate volt generated by the intermediate bus converter 104 to a load voltage (0.8 volts in FIG. 1) suitable for powering the load circuit 108. The voltage regulator can be a multiphase regulator in some examples. The voltage regulator 106 has an input coupled to the output of the intermediate bus converter 104, via a conductor of the substrate 102, for receipt of the intermediate voltage. The voltage regulator 106 has an output (one or more outputs in various examples) at which the load voltage is provided.

The load circuit 108 can be a processor (e.g., a general-purpose processor, a graphics processing unit, an artificial intelligence processor, etc.) or any other electronic circuit. The load circuit 108 has an input (e.g., one or more inputs), coupled to the output of the voltage regulator 106, for receiving the load voltage. The load circuit 108 can consume significant power. For example, some examples of the load circuit 108 can consume 1000 watts or more. Accordingly, the currents flowing from the intermediate bus converter 104 and the load circuit 108 can be large.

By converting the input voltage to the load voltage in multiple stages, each stage can be optimized to provide higher conversion efficiency than would be provided by a single converter that converts the input voltage to the load voltage. The intermediate bus converter 104 can include transformers having cores with multiple secondary cells coupled to each core to reduce the physical size of the intermediate bus converter 104, and reduce the loss attributable to the transformers.

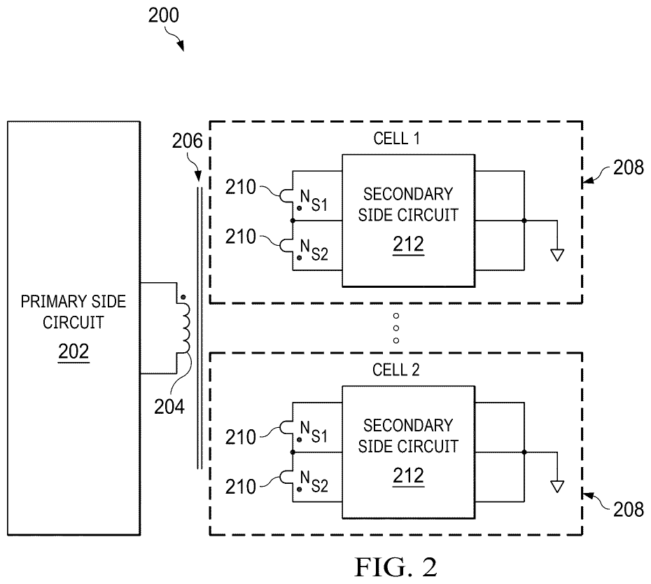

FIG. 2 is a schematic of an example converter 200. The converter 200 can be an example of the intermediate bus converter 104. The converter 200 includes a primary side circuit 202, a primary winding 204, a core 206, and two or more secondary cells 208. The primary side circuit 202 is coupled to the primary winding 204, and includes circuitry that drives the primary winding 204 for transfer of energy from the primary side of the converter 200, to the secondary side of the converter 200. For example, the primary side circuit 202 can include transistors that drive the primary winding 204, and a controller configured to control turn-on and turn-off of the transistors.

The core 206 can be a magnetic core or an air core. For example, the core 206 can include a magnetic post (e.g., a ferrite post) or an air column. The cross-section of the core can be round, oblong, elliptical, square, rectangular, etc.

The primary winding 204 includes a conductor that is wound around the core 206. The conductor can be provided in one or more metal layers of a substrate, such as a PCB, a package substrate, or other laminate substrate.

A secondary cell 208 includes a secondary winding 210, and a secondary circuit 212. The secondary circuit 212 is coupled to the secondary winding 210 and includes circuitry for rectifying the current flowing in the secondary winding 210. For example, the secondary circuit 212 can include transistors and capacitors coupled to the secondary winding 210, and a controller configured to control switching of the transistors. The secondary circuit 212 can include terminals coupled to the secondary winding 210 and coupled to a reference terminal (e.g., ground). In FIG. 2, the secondary circuit 212 includes terminals coupled to two ends and a center tap of the secondary winding 210.

The secondary winding 210 includes a conductor that is wound around the core 206. The conductor can be provided in one or more metal layers of the substrate, such as a PCB or other laminate substrate. The secondary winding 210 may be formed on different metal layers than the primary winding 204.

The converter 200 can include more than one example of the secondary cell 208, with each secondary cell 208 including a secondary winding 210 wound around the core 206, and a secondary circuit 212 coupled to the secondary winding 210. The secondary circuits 212 can be coupled a common direct current (DC) terminal. The DC terminal can include a common power output or a common ground. In some examples, each secondary cell 208 can represent a phase of a multiphase converter. Different examples of the secondary winding 210 can be provided on different metal layers of the substrate. Multiple examples of the secondary winding 210 provided around the core 206 allow transformer size to be reduced. Examples of the secondary circuit 212 can be placed around the core 206, and on one or both sides of the substrate to reduce loss.

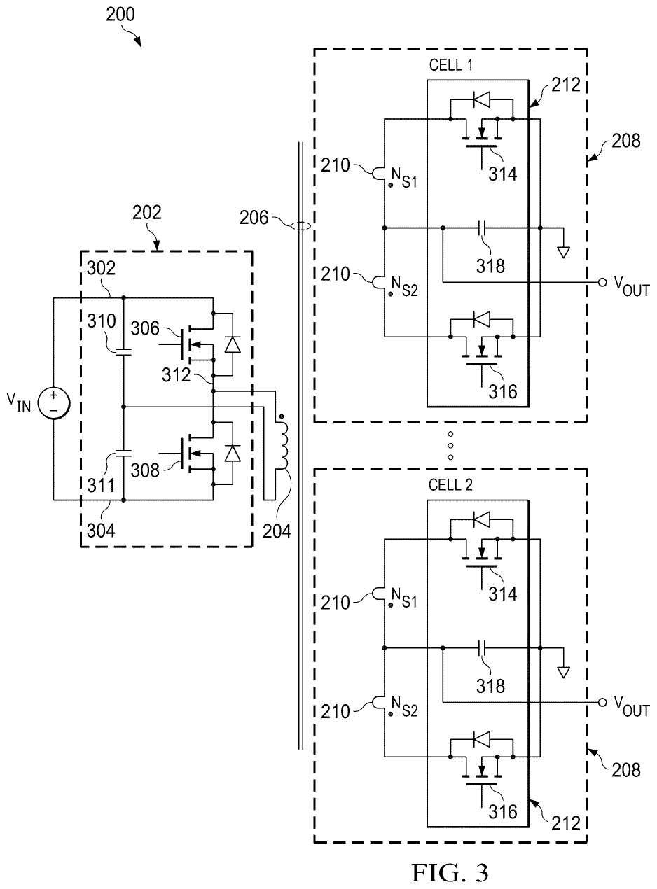

FIG. 3 is a lower level schematic of the converter 200 showing example circuitry of the primary side circuit 202 and the secondary cell 208. The primary side circuit 202 includes transistors 306 and 308, and capacitors 310 and 311. The transistors 306 and 308 can be N-channel metal oxide semiconductor field effect transistors (NFETs) or other transistor types (e.g., SiC or GaN). Body diodes of the transistors 306 and 308 are illustrated for reference. An input voltage VIN is provided between terminals 302 and 304. The capacitor 310 has a first terminal coupled to the terminal 302 and a second terminal. The capacitor 311 has a first terminal coupled to the second terminal of the capacitor 310, and a second terminal coupled to the terminal 304. The transistor 306 has a first terminal (e.g., drain) coupled to the terminal 302, a second terminal (e.g., source) coupled to a switching terminal 312, and a control terminal (e.g., gate) coupled to a control circuit (not shown). The transistor 308 has a first terminal (e.g., drain) coupled to the switching terminal 312, a second terminal (e.g., source) coupled to the terminal 304, and a control terminal (e.g., gate) coupled to the control circuit.

The primary winding 204 has a first end and a second end. The first end of the primary winding 204 is coupled to the switching terminal 312, and the second end of the primary winding 204 is coupled to the first terminal of the capacitor 311 and the second terminal of the capacitor 310. The transistors 306 and 308 can be switched on and off to provide current flow through the primary winding 204.

The secondary cell 208 includes the secondary winding 210 and the secondary circuit 212. The example of the secondary winding 210 shown in FIG. 3 has a first end, a second end and a center tap. The secondary circuit 212 include transistors 314 and 316, and a capacitor 318. The transistors 314 and 316 can be N-channel metal oxide semiconductor field effect transistors (NFETs) or other transistor types (e.g., SiC or GaN). Body diodes of the transistors 314 and 316 are illustrated for reference. The transistors 314 and 316 operate as synchronous rectifiers.

The capacitor 318 has a first terminal coupled to the center tap of the secondary winding 210, and a second terminal coupled to a reference terminal (e.g., ground). The center tap of the secondary winding 210 is also coupled to an output terminal V_{OUT}. The transistor 314 has a first terminal (e.g., drain) coupled to the first end of the secondary winding 210, a second terminal (e.g., source) coupled to the reference terminal, and a control terminal (e.g., gate) coupled to a synchronous rectifier control circuit (not shown). The transistor 316 has a first terminal (e.g., drain) coupled to the second end of the secondary winding 210, a second terminal (e.g., source) coupled to the reference terminal, and a control terminal (e.g., gate) coupled to the synchronous rectifier control circuit. The transistors 314 and 316 can be switched on and off to provide a rectified voltage at V_{OUT}.

As explained with regard to FIG. 2, the converter 200 can include any number of secondary cells 208 arranged around the core 206. The primary side circuit 202, the primary winding 204, and any number of the secondary cells 208 can be provided on a substrate (e.g., a package substrate) as part of a packaged integrated circuit.

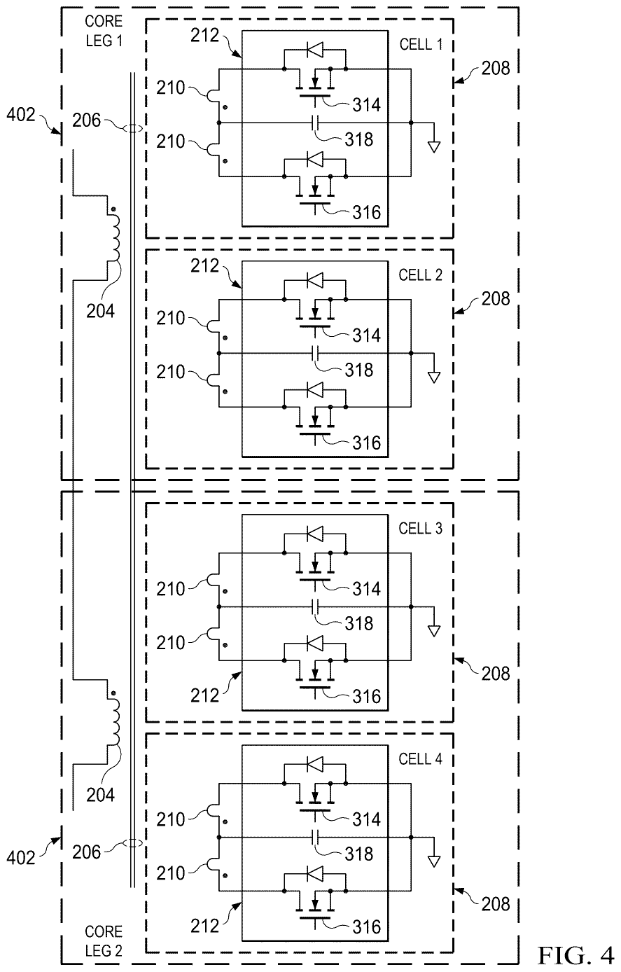

FIG. 4 is a schematic of a converter including multiple core legs and multiple secondary cells coupled to each core leg. The converter of FIG. 4 includes two or more of the circuits 402, where each circuit 402 is a core leg. The circuit 402 includes the primary winding 204, the core 206 and any number of secondary cells 208. An example of the primary side circuit 202 can drive the primary winding 204. In the circuits 402, the cores 206 of at least two examples of the circuit 402 can be magnetically coupled (e.g., sharing a same magnetic flux), and the primary winding 204 of the different examples of the circuit 402 can be provided as a single conductor wound around the cores 206. Any number of secondary cells 208 can be arranged around each of the cores 206. In FIG. 4, each core leg includes two secondary cells 208. Some examples can include more than secondary cells in a core leg.

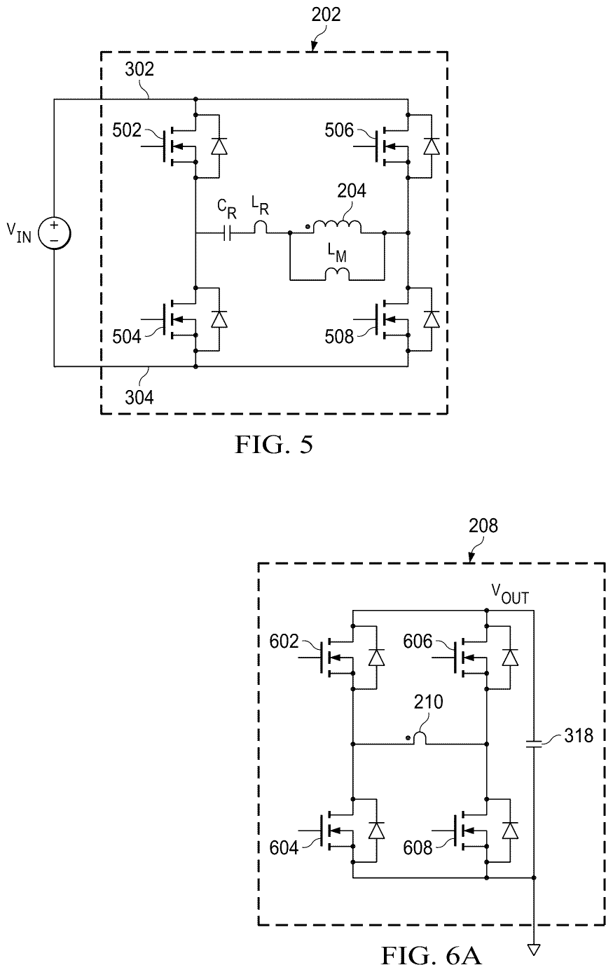

FIG. 5 is a schematic of an example primary side circuit 202 including a full bridge (a full bridge LLC circuit). The primary side circuit 202 is a full bridge circuit and includes the primary winding 204, and transistors 502, 504, 506, and 508. Magnetizing inductance (L_{M}), resonant inductance (L_{R}), and resonant capacitance (C_{R}) are illustrated for reference. The transistors 502, 504, 506, and 508 can be N-channel metal oxide semiconductor field effect transistors (NFETs) or other transistor types (e.g., SiC or GaN). Body diodes of the transistors 502, 504, 506, and 508 are illustrated for reference. A voltage source V_{IN} is shown for reference coupled between the terminals 302 and 304.

The transistors 502, 504, 506, and 508 are coupled as a full bridge. The transistor 502 has first terminal (e.g., drain) coupled to the terminal 302, a second terminal (e.g., source) coupled to the first end of the primary winding 204, and a control terminal (e.g., gate) coupled to a control circuit (not shown). The transistor 504 has a first terminal (e.g., drain) coupled to the first end of the primary winding 204, a second terminal (e.g., source) coupled to the terminal 304, and a control terminal (e.g., gate) coupled to the control circuit. The transistor 506 has first terminal (e.g., drain) coupled to the terminal 302, a second terminal (e.g., source) coupled to the second end of the primary winding 204, and a control terminal (e.g., gate) coupled to a control circuit. The transistor 508 has a first terminal (e.g., drain) coupled to the second end of the primary winding 204, a second terminal (e.g., source) coupled to the terminal 304, and a control terminal (e.g., gate) coupled to the control circuit. The transistors 502, 504, 506, and 508 can be switched on and off to provide current flow through the primary winding 204.

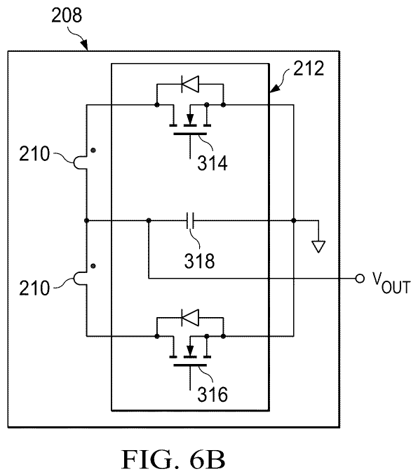

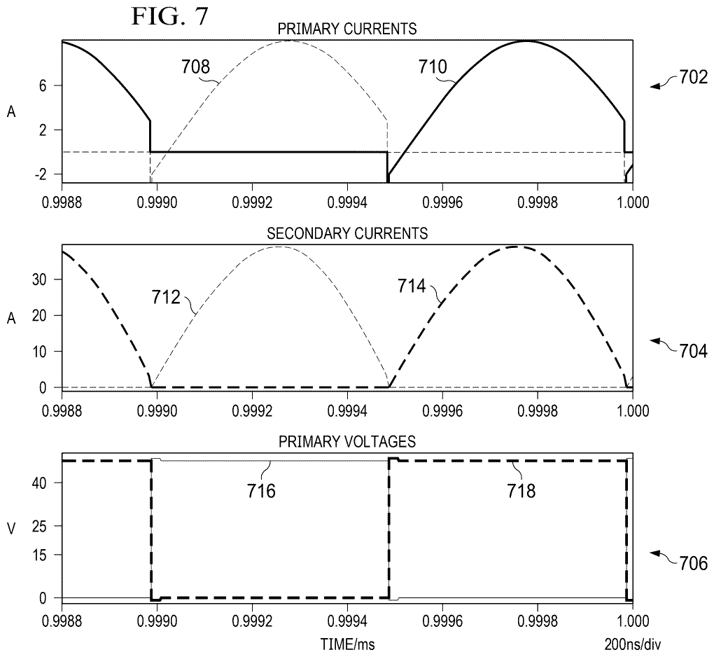

FIG. 6A is a schematic of an example secondary cell 208. In FIG. 6A, the secondary cell 208 is a rectifier circuit (a full bridge circuit) and includes the secondary winding 210, the capacitor 318, and transistors 602, 604, 606, and 608. Magnetizing inductance (L_{M}), resonant inductance (L_{R}), and resonant capacitance (C_{R}) are illustrated for reference. The transistors 602, 604, 606, and 608 can be N-channel metal oxide semiconductor field effect transistors (NFETs) or other transistor types (e.g., SiC or GaN). Body diodes of the transistors 602, 604, 606, and 608 are illustrated for reference. The capacitor 318 is coupled between a voltage output terminal V_{OUT} and the reference terminal.

The transistors 602, 604, 606, and 608 are coupled as a full bridge, and operate as synchronous rectifiers. The transistor 602 has a first terminal (e.g., drain) coupled to V_{OUT}, a second terminal (e.g., source) coupled to the first end of the secondary winding 210, and a control terminal (e.g., gate) coupled to a synchronous rectifier control circuit (not shown). The transistor 604 has a first terminal (e.g., drain) coupled to the first end of the secondary winding 210, a second terminal (e.g., source) coupled to the reference terminal, and a control terminal (e.g., gate) coupled to the synchronous rectifier control circuit. The transistor 606 has first terminal (e.g., drain) coupled to V_{OUT}, a second terminal (e.g., source) coupled to the second end of the secondary winding 210, and a control terminal (e.g., gate) coupled to the synchronous rectifier control circuit. The transistor 608 has a first terminal (e.g., drain) coupled to the second end of the secondary winding 210, a second terminal (e.g., source) coupled to the reference terminal, and a control terminal (e.g., gate) coupled to the synchronous rectifier control circuit. The transistors 602, 604, 606, and 608 can be switched on and off to provide a rectified voltage at the V_{OUT}.

FIG. 6B is a schematic of a second example secondary cell 208. The secondary cell 208 is a rectifier circuit, and includes the secondary winding 210, and the secondary circuit 212. The secondary winding 210 has a first end, a second end, and a center tap. The secondary circuit 212 includes the transistors 314 and 316, and the capacitor 318. The transistors 314 and 316 can be N-channel metal oxide semiconductor field effect transistors (NFETs) or other transistor types (e.g., SiC or GaN). Body diodes of the transistors 314 and 316 are illustrated for reference. The transistors 314 and 316 operate as synchronous rectifiers.

The capacitor 318 has a first terminal coupled to the center tap of the secondary winding 210, and a second terminal coupled to a reference terminal (e.g., ground). The center tap of the secondary winding 210 is also coupled to an output terminal V_{OUT}. The transistor 314 has a first terminal (e.g., drain) coupled to the first end of the secondary winding 210, a second terminal (e.g., source) coupled to the reference terminal, and a control terminal (e.g., gate) coupled to a synchronous rectifier control circuit (not shown). The transistor 316 has a first terminal (e.g., drain) coupled to the second end of the secondary winding 210, a second terminal (e.g., source) coupled to the reference terminal, and a control terminal (e.g., gate) coupled to the synchronous rectifier control circuit. The transistors 314 and transistor 316 can be switched on and off to provide a rectified voltage at the V_{OUT}.

FIG. 7 is a graph of example voltage and current in an example of the converter 200 using the primary side circuit 202 of FIG. 5 and the secondary cell 208 of FIG. 6B. The graph 702 shows current in the primary side circuit 202. Curve 708 is current through the transistors 502 and 508. Curve 710 is current through the transistors 502 and 508. The graph 702 shows that switching in the primary side circuit 202 occurs at or about zero current.

The graph 704 shows current in the secondary cell 208. The curve 712 is current through the transistor 316. The curve 714 is current through the transistor 314. The graph 704 shows that switching in the secondary cell 208 occurs at or about zero current.

The graph 706 shows voltage in the primary side circuit 202. The curve 716 is drain-to-source voltage of the transistor 506. The curve 718 is drain-to-source voltage of the transistor 502. The graph 706 shows that switching in the primary side circuit 202 occurs at or about zero volts.

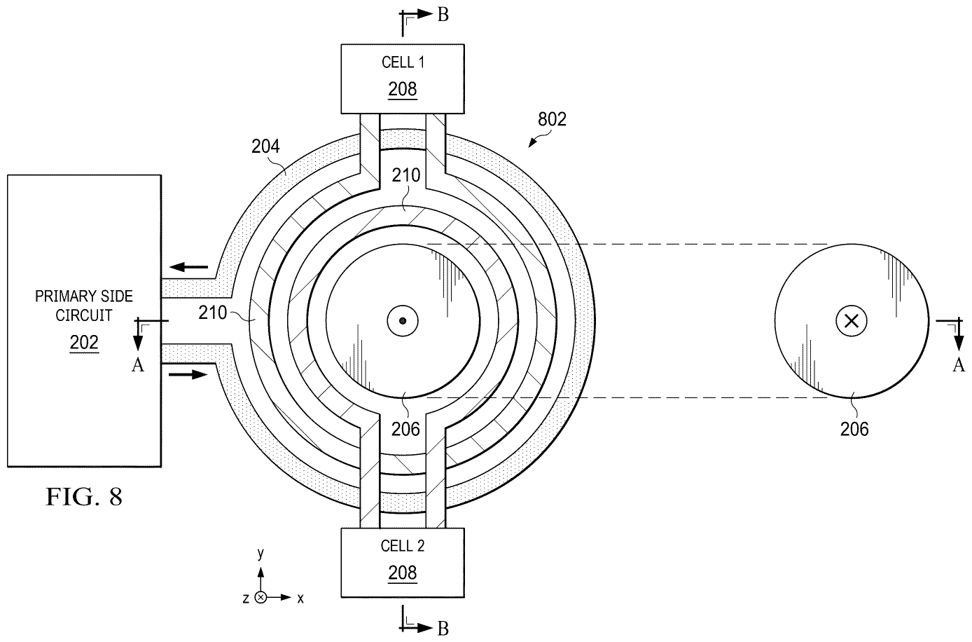

FIG. 8 is a top view of an example representation of the converter 200. In FIG. 8, a transformer 802 includes the core 206, the primary winding 204, and two examples of the secondary winding 210 around the core 206. The primary winding 204 and the secondary windings 210 can be on different metal layers of a substrate. The primary side circuit 202 and examples of the secondary cell 208 can be provided on an outer layer of the substrate. The primary side circuit 202 is coupled to the primary winding 204, and each example of the secondary cell 208 is coupled to a different example of the secondary winding 210. Multiple examples of the secondary winding 210 are around the core 206, and a secondary cell 208 is coupled to each secondary winding 210. A second example of the core 206 is included in FIG. 8 to provide a flux return path in the transformer 802. The multiple examples of the secondary winding 210 around the core 206 reduce the size of the transformer 802, and the multiple examples of the secondary cell 208 reduce termination loss. The secondary cells 208 can be on opposite sides of the core 206, or positioned around the core 206 to facilitate connection to the secondary winding 210 or connection to other circuits.

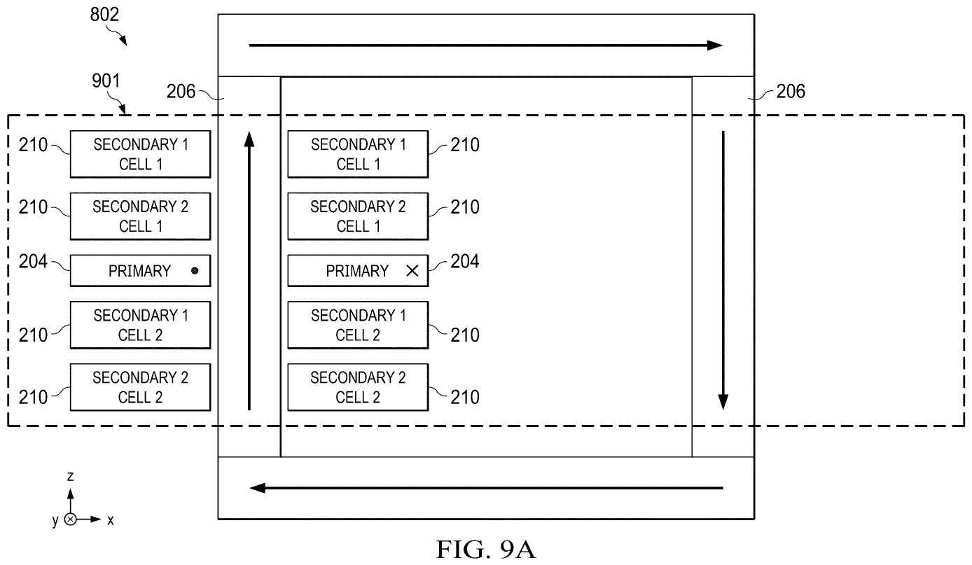

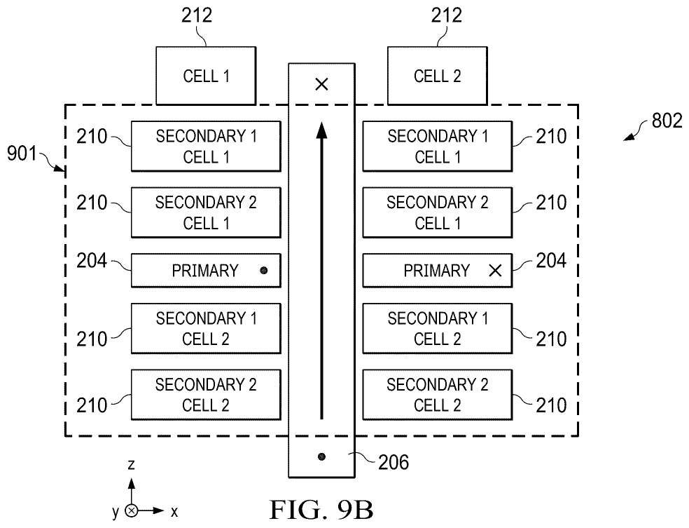

FIG. 9A is a cross-sectional view of the transformer 802 taken along plane A-A in FIG. 8. FIG. 9A shows the primary winding 204 around the core 206, the secondary winding 210 of cell 1 around the core 206, and the secondary winding 210 of cell 2 around the core 206. In each cell, the secondary winding 210 includes a first portion labeled secondary 1 and second portion labeled secondary 2. The primary winding 204, and portions of secondary 1 and secondary 2 of the secondary winding 210 can be provided on different metal layers of a substrate 901. The substrate 901 can a PCB or other multilayer substrate.

FIG. 9B is a cross-sectional view of the converter 200 taken along plane B-B in FIG. 8. FIG. 9B shows the primary winding 204 around the core 206, the secondary winding 210 of cell 1 around the core 206, the secondary winding 210 of cell 2 around the core 206, the secondary circuit 212 of cell 1, and the secondary circuit 212 of cell 2. The secondary circuit 212 of cell 1, and the secondary circuit 212 of cell 2 can be provided on an outer layer of the substrate 901 on opposite sides of the core 206. In FIGS. 9A and 9B, the primary winding 204 is shown positioned between the secondary windings 210 of cell 1 and cell 2. In some examples of the transformer 802, a first portion of the primary winding 204 can be provided between portions secondary 1 and secondary 2 of cell 1, and a second portion of the primary winding 204 can be provided between portions secondary 1 and secondary 2 of cell 2.

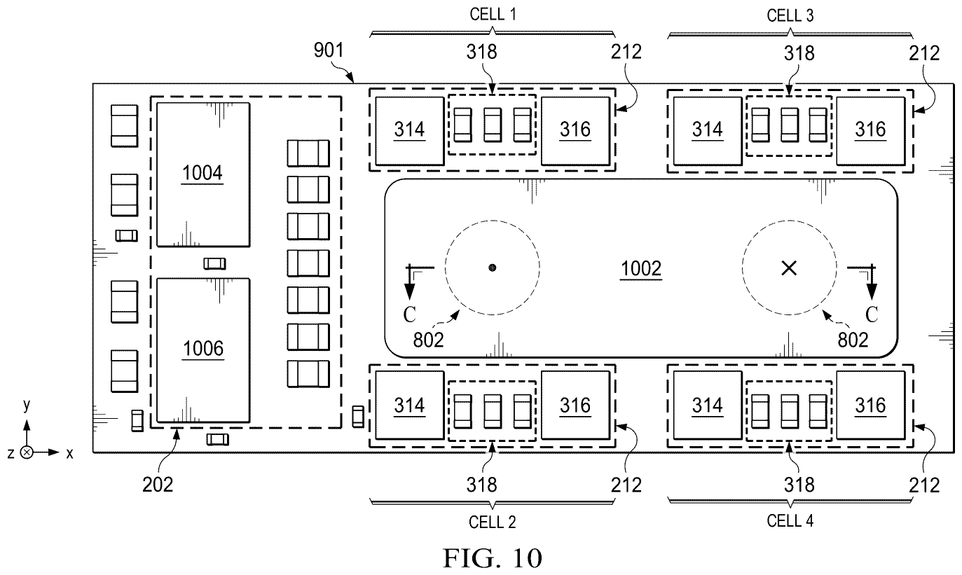

FIG. 10 is a top view of an example of the converter of FIG. 4. The converter includes the substrate 901, a core structure 1002, the primary side circuit 202, and four examples of the secondary circuit 212. The core structure 1002 includes two magnetic posts (two examples of the core 206) that pass into and/or through the substrate 901. A primary winding 204 and to examples of the secondary winding 210 are wound around each core 206 to provide two examples of the transformer 902.

The primary side circuit 202 includes integrated circuits 1004 and 1006. The integrated circuit 1004 can include the transistor 502 and the transistor 504. The integrated circuit 1006 can include the transistor 506 and the transistor 508. The transistors 502, 504, 506, and 508 can be coupled to the primary winding 204 as shown in FIG. 5.

Each example of the secondary circuit 212 can include the transistors 314 and 316 (shown as packaged integrated circuits) and the capacitor 318, which can be coupled to an example of the secondary winding 210 as shown in FIG. 6B. Examples of the secondary circuit 212 are placed on opposite sides of the transformer 902.

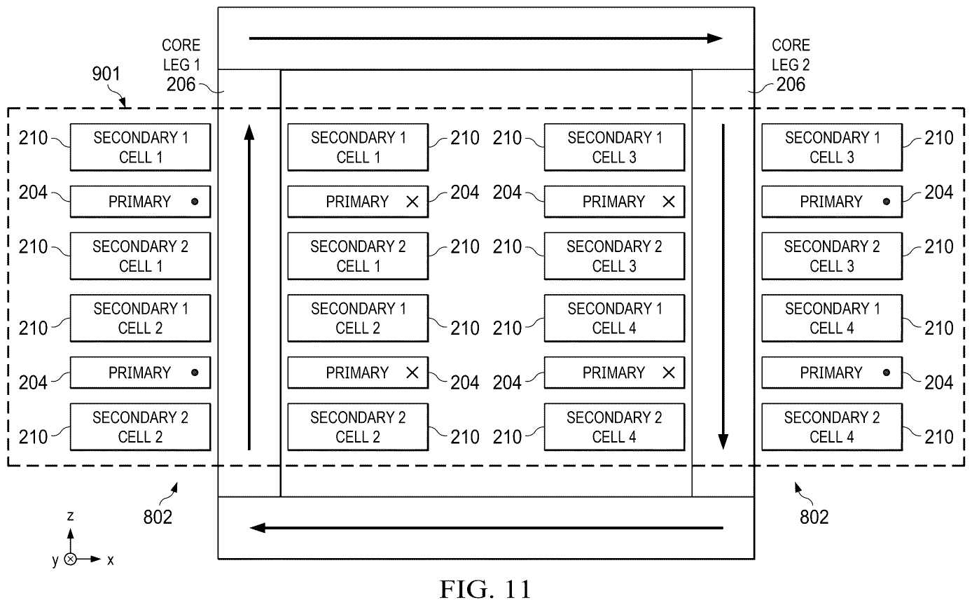

FIG. 11 is a cross-sectional view of the transformers 802 of FIG. 10 taken along plane C-C. FIG. 11 shows a first example of the transformer 802 including the primary winding 204 around a first core 206, the secondary winding 210 of cell 1 around the first core 206, and the secondary winding 210 of cell 2 around the first core 206. FIG. 11 also shows a second example of the transformer 802 including the primary winding 204 around a second core 206, the secondary winding 210 of cell 3 around the second core 206, and the secondary winding 210 of cell 4 around the second core 206. In FIG. 11, a first portion of the primary winding 204 is provided between portions secondary 1 and secondary 2 of cell 1, a second portion of the primary winding 204 can be provided between portions secondary 1 and secondary 2 of cell 2, a third portion of the primary winding 204 can be provided between portions secondary 1 and secondary 2 of cell 3, and a fourth portion of the primary winding 204 can be provided between portions secondary 1 and secondary 2 of cell 4.

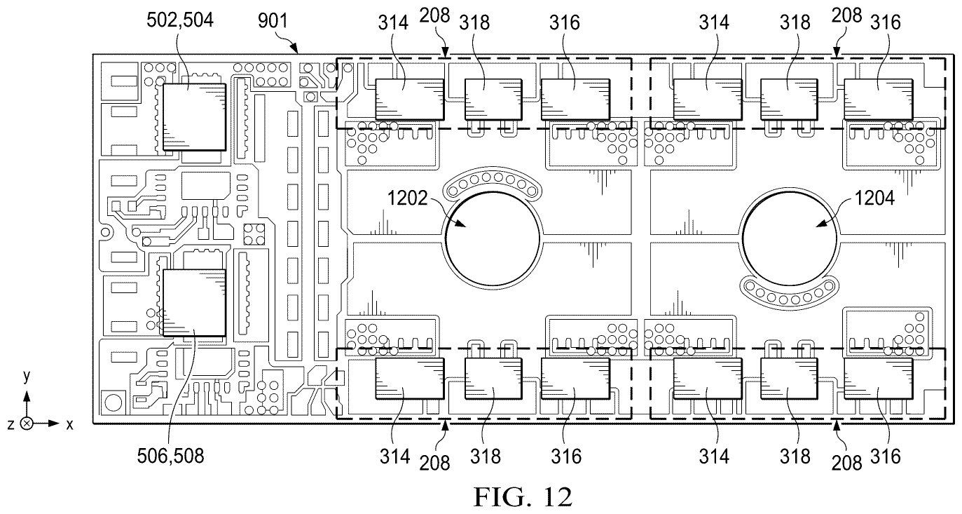

FIG. 12 is a top view of an example layer of a substrate 901 suitable for use in the converter 200. FIG. 12 shows a top layer of a PCB in some examples. The substrate 901 includes apertures 1202 and 1204 into which the core 206 can be inserted. Connection pads for placement of the transistors 502, 504, 506, and 508 (e.g., the integrated circuits 1004 and 1006) are provided in the top metal layer of the substrate 901. Connection pads for multiple examples of the secondary cell 208 (the transistor 314, the transistor 316, and the capacitor 318) are also provided in the top metal layer of the substrate 901. In some examples of the substrate 901 connection pads for at least some components can be provided in a bottom metal layer of the substrate 901.

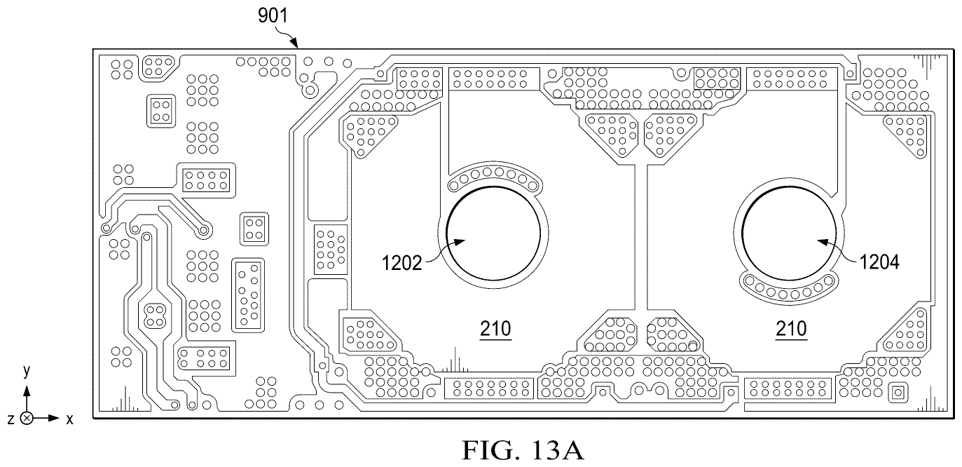

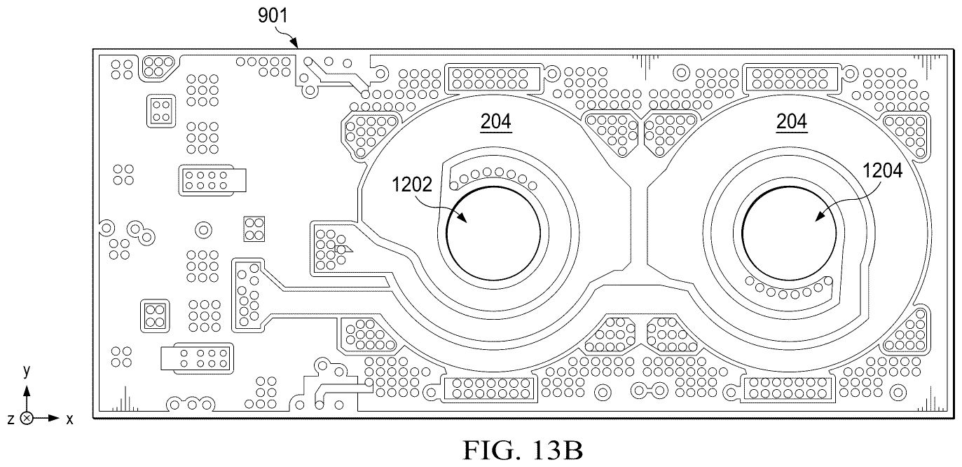

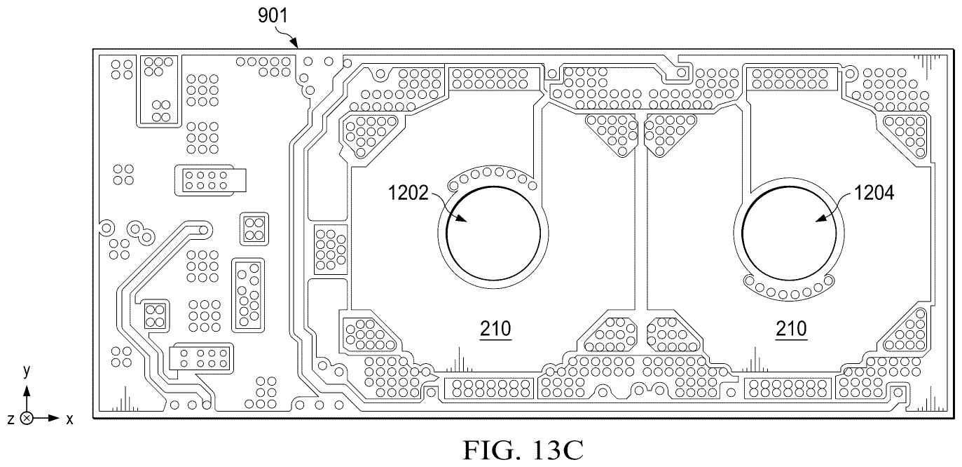

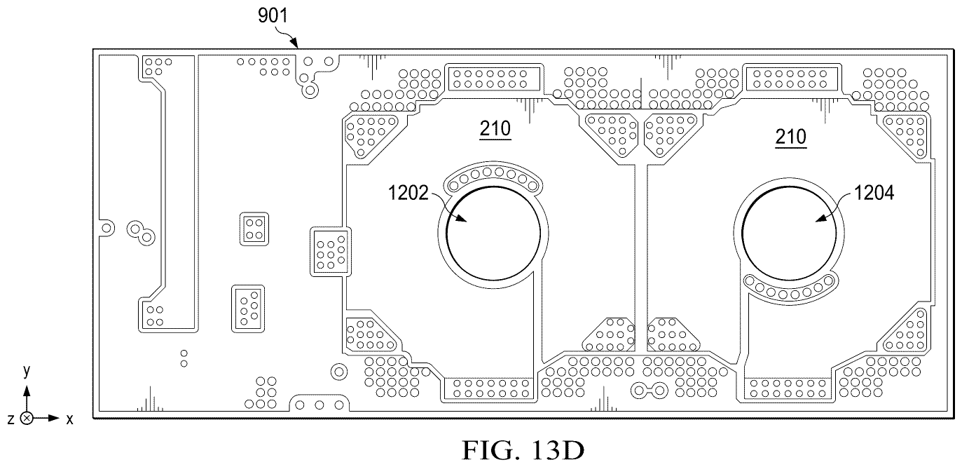

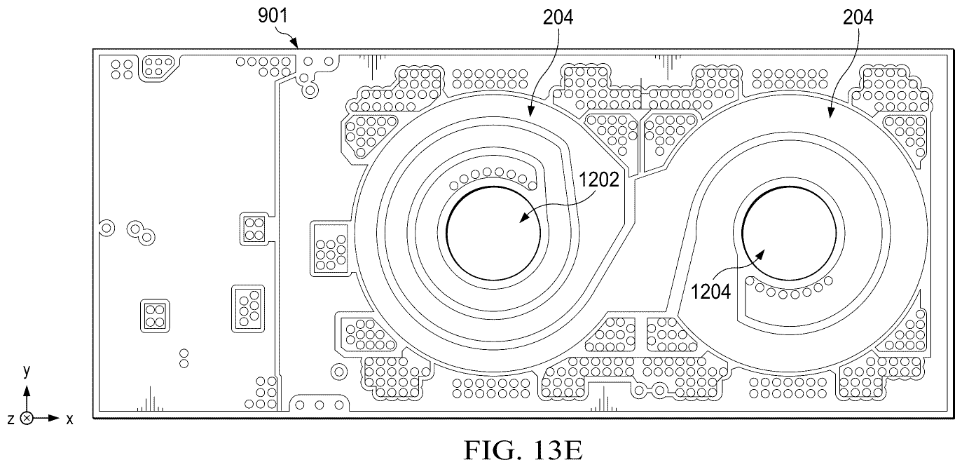

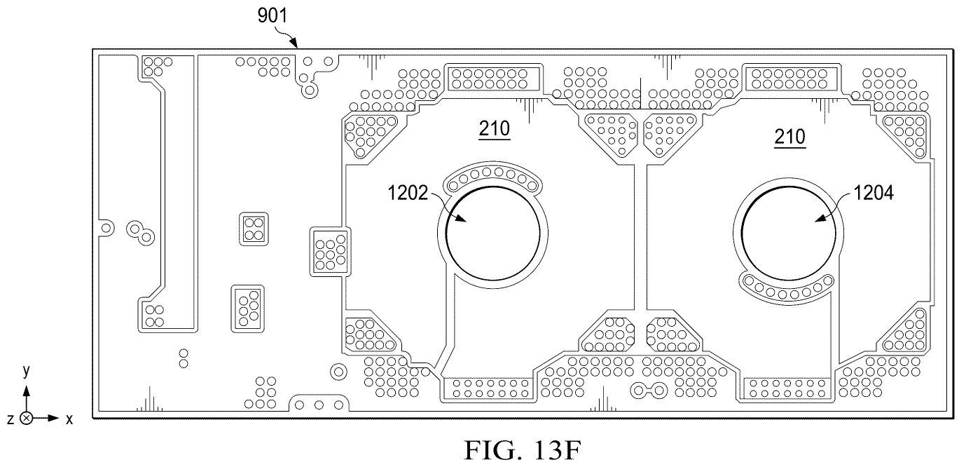

FIGS. 13A-13E are top views of example internal metal layers of the substrate 901 suitable for use in the converter of FIG. 4. FIG. 13A is a top view of a first internal metal layer of the substrate 901, which includes a first portion of a first secondary winding 210 about the aperture 1202, and a first portion of a third secondary winding 210 about the aperture 1204. FIG. 13B is a top view of a second internal metal layer of the substrate 901, which includes a first portion of the primary 204 about the aperture 1202, and a second portion of the primary 204 about the aperture 1204. FIG. 13C is a top view of a third internal metal layer of the substrate 901, which includes a second portion of the first secondary winding 210 about the aperture 1202, and a second portion of the third secondary winding 210 about the aperture 1204.

FIG. 13D is a top view of a fourth internal metal layer of the substrate 901, which includes a first portion of a second secondary winding 210 about the aperture 1202, and a first portion of a fourth secondary winding 210 about the aperture 1204. FIG. 13E is a top view of a fifth internal metal layer of the substrate 901, which includes a third portion of the primary 204 about the aperture 1202, and a fourth portion of the primary 204 about the aperture 1204. FIG. 13F is a top view of a sixth internal metal layer of the substrate 901, which includes a second portion of the second secondary winding 210 about the aperture 1202, and a second portion of the fourth secondary winding 210 about the aperture 1204.

Some examples of the substrate 901 can include a different number of metal layers to provide a different number of secondary windings 210 and/or portions of the primary winding 204 for use with a different number of secondary cells 208.

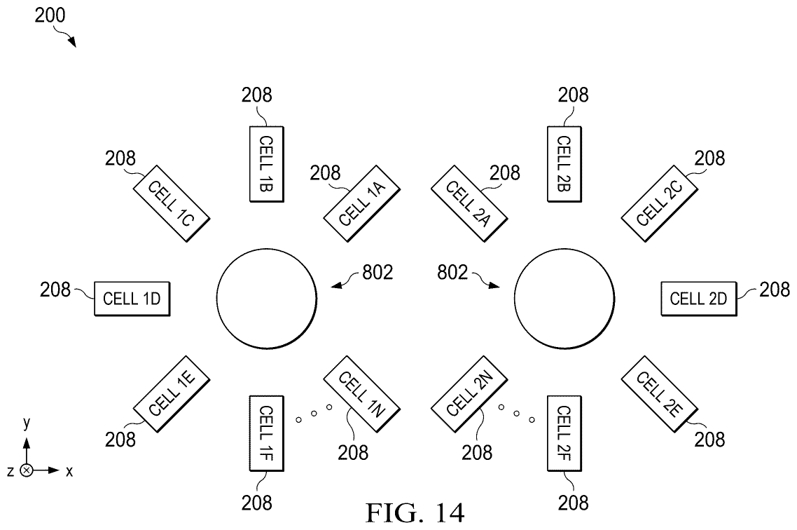

FIG. 14 is a top view of an example converter 200 that includes multiple secondary cells coupled to each core. In FIG. 12, the converter 200 includes two transformers 802. Some examples of the converter 200 can include more than two transformers 802. Each transformer 802 includes a core 206, a primary winding 204, and multiple (N) examples of the secondary winding 210. The converter 200 also include N examples of the secondary cell 208 distributed around each transformer 802 (e.g., a secondary cell 208 for each secondary winding 210) to reduce termination loss. Each secondary cell 208 includes synchronous rectifiers (e.g., transistors arranged as a full bridge or a center tap circuit as in FIG. 6A or 6B), and the capacitor 318. The outputs VOUT of any number of the secondary cells 208 can be connected together as a single bus. The secondary winding 210 are in the metal layers of the substrate 901, and the secondary circuit 212 of each secondary cell 208 can be placed on either side (top or bottom) of the substrate 901 around the core 206.

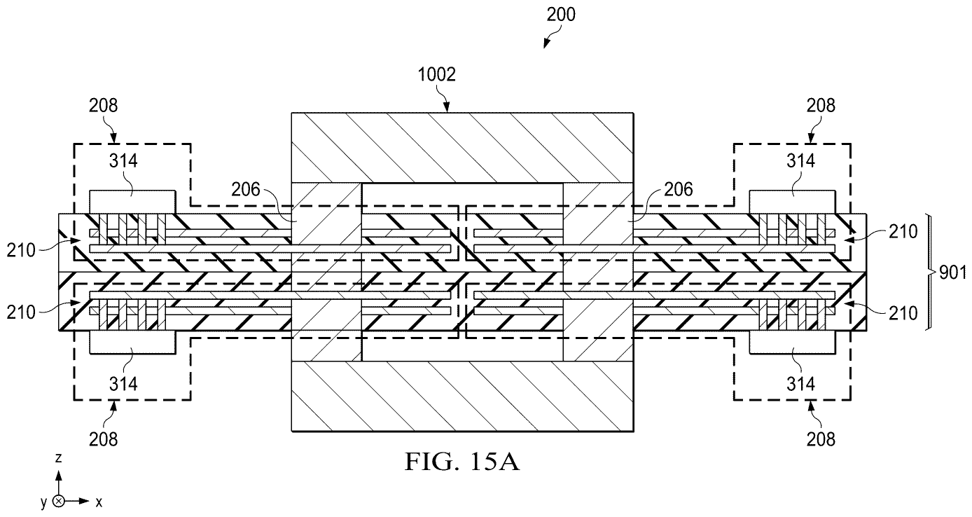

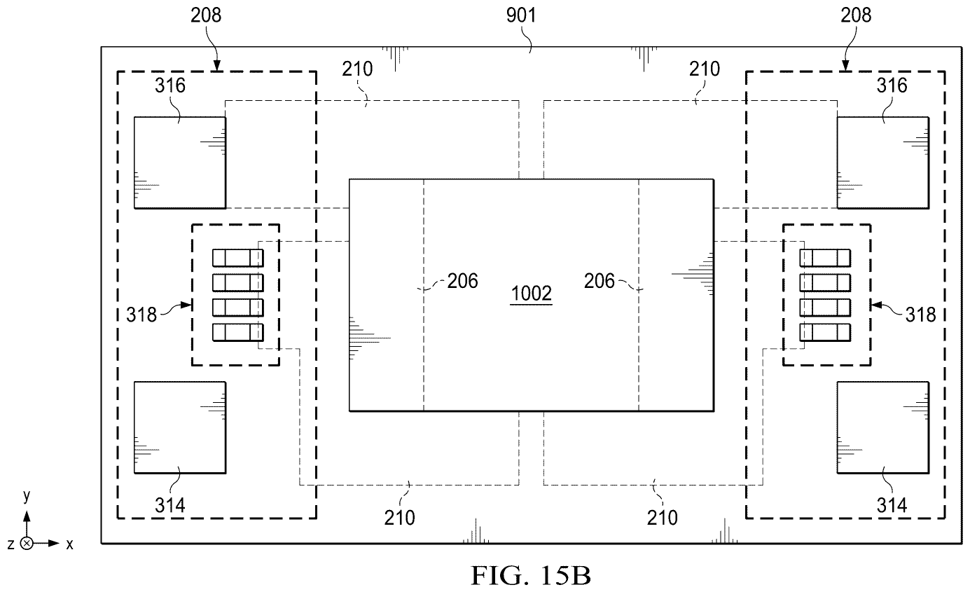

FIGS. 15A and 15B are cross-sectional and top views of an example of the converter of FIG. 4. Two examples of the core 206 pass through the substrate 901, with two examples of the secondary cell 208 coupled to each core 206, where each secondary cell 208 includes a secondary winding 210 around the core 206, and transistors 314 and 316 coupled to the secondary winding 210. FIG. 15A shows the two examples of the secondary cell 208 coupled to a core 206 placed on opposite sides of the substrate 901. FIG. 15A shows that, in some examples, the secondary cells 208 on opposite sides of the substrate 901 are not electrically coupled to one another (e.g., the secondary winding 210 of one secondary cell 208 is not coupled to the secondary winding 210 of the other secondary cell 208). The secondary winding 210 can be coupled to the transistor 314 using blind vias in the substrate 901, thereby isolating the secondary windings 210 from one another. In some examples, the secondary cells 208 on opposite sides of the substrate 901 are electrically coupled to one another (e.g., the secondary winding 210 of one secondary cell 208 is coupled to the secondary winding 210 of the other secondary cell 208).

The top view of FIG. 15B also shows the capacitors 318 of the secondary cells 208, where each capacitor 318 can include multiple capacitor coupled in parallel between a center tap of the secondary winding 210 and a reference terminal. In some examples, the output terminals (V_{OUT}) and/or the reference terminals (e.g., ground) of multiple secondary cells 208 may be connected to provide a common DC and/or ground bus.

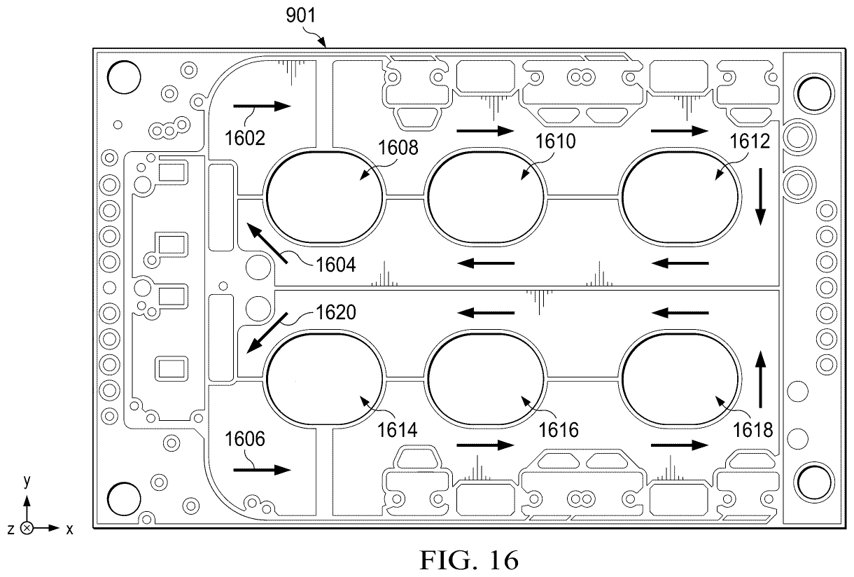

FIG. 16 is a top view of an example layer of the substrate 901 showing examples of primary windings. The illustrated layer of the substrate 901 includes metal conductors of primary windings. Apertures 1408-1418 of the substrate 901 allow passage of multiple examples of the core 206 through the substrate 901. A first primary winding can start at the about the arrow 1602 and pass around the apertures 1608-1612 to the arrow 1604 as illustrated by the intervening arrows. In some examples, at the arrow 1604, the first primary winding can pass through a via to a second layer of the substrate 901 and wrap around the apertures 1608-1612 on the second layer. A second primary winding can start at the arrow 1606 and pass around the apertures 1614, 1616, and 1618 to the arrow 1620. In some examples, at the arrow 1620, the second primary winding can pass through a via to the second layer of the substrate 901 and wrap around the apertures 1614-1618 on the second layer. The first and second primary windings can be connected in parallel in some examples.

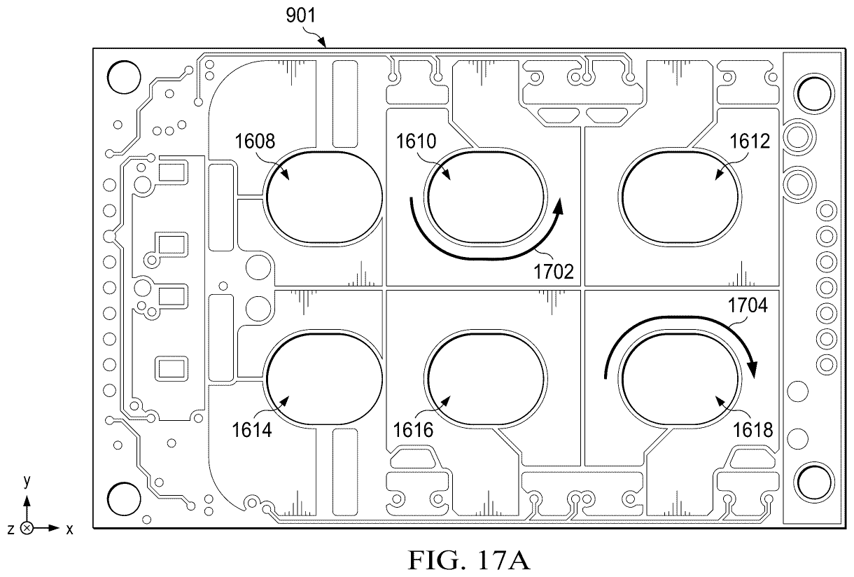

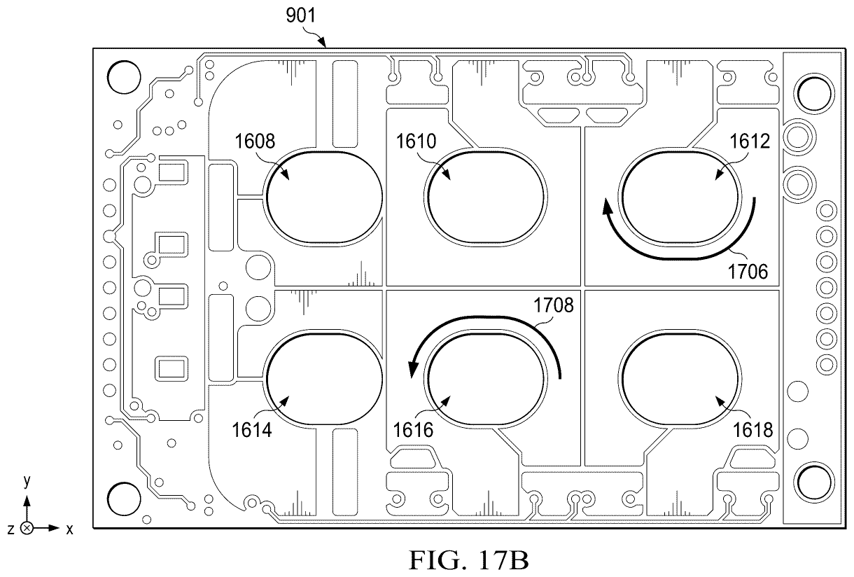

FIGS. 17A and 17B are top views of an example layer of the substrate 901 showing secondary windings. FIG. 17A shows a first secondary winding around the aperture 1610 in the direction of the arrow 1702, and a second secondary winding around the aperture 1618 in the direction of the arrow 1704. FIG. 17B shows a third secondary winding around the aperture 1612 in the direction of the arrow 1706, and a fourth secondary winding around the aperture 1616 in the direction of the arrow 1708. Additional secondary windings can be provided on different metal layers of the substrate 901.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor (“FET”) (such as an n-channel FET (NFET), or a p-channel FET (PFET)), a n-type metal-oxide semiconductor field-effect transistors (nMOSFET or just “nMOS”), a bipolar junction transistor (BJT—e.g., NPN transistor or PNP transistor), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SIC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” means that the conduction channel of the FET is present and drain current may flow through the FET. References herein to a FET being “off” means that the conduction channel is not present and drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. An apparatus comprising:
a substrate including first, second, and third metal layers;
a core in the substrate;
a primary side circuit, a first secondary side circuit, and a second secondary side circuit on the substrate;
a primary winding in the first metal layer of the substrate, the primary winding wrapping around the core and coupled to the primary side circuit;
a first secondary winding in the second metal layer of the substrate, the first secondary winding wrapping around the core and coupled to the first secondary side circuit;
and a second secondary winding in the third metal layer of the substrate, the second secondary winding wrapping around the core and coupled to the second secondary side circuit.

2. The apparatus of claim 1, wherein the primary side circuit includes a full bridge circuit.

3. The apparatus of claim 2, wherein at least one of the first or second secondary side circuits includes a full bridge circuit.

4. The apparatus of claim 2, wherein the first secondary winding has a center tap between a first end and a second end of the first secondary winding, the first secondary side circuit includes a first rectifier circuit coupled to the first end and a second rectifier circuit coupled to the second end.

5. The apparatus of claim 4, wherein each of the first and second rectifier circuits includes a respective transistor and a respective diode.

6. The apparatus of claim 5, wherein the diode is a body diode of the transistor.

7. The apparatus of claim 2, wherein the first and second secondary side circuits are coupled to a common direct current (DC) terminal.

8. The apparatus of claim 7, wherein the common DC terminal includes at least one of: a common power output, or a common ground.

9. The apparatus of claim 1, wherein the core is a first core, the substrate includes a second core, and the primary winding wraps around the first and second cores.

10. The apparatus of claim 9, further comprising:
a third secondary side circuit on the substrate; and
a third secondary winding in the second or third metal layers of the substrate, the third secondary winding wrapping around the second core and coupled to the third secondary side circuit on the substrate.

11. The apparatus of claim 1, wherein the substrate has opposite first and second surfaces; and
wherein the primary side circuit and the first secondary side circuit are on the first surface, and the second secondary side circuit is on the second surface.

12. The apparatus of claim 1, wherein the primary side circuit, the primary winding, the first and second secondary side circuits, and the first and second secondary windings are part of a multiphase power converter.

13. The apparatus of claim 1, wherein the substrate is a printed circuit board.

14. The apparatus of claim 1, wherein the substrate is a package substrate, and the primary side circuit, the first and second secondary side circuits, and the package substrate are part of a packaged integrated circuit.

15. A power converter comprising:
a substrate including first, second, and third metal layers;
a core in the substrate;
a primary winding in the first metal layer of the substrate, the primary winding wrapping around the core;
a first secondary winding in the second metal layer of the substrate, the first secondary winding wrapping around the core; and
a second secondary winding in the third metal layer of the substrate, the second secondary winding wrapping around the core;
a primary side circuit including a first transistor and a second transistor respectively coupled to a first end and a second end of the primary winding;
a first secondary side circuit including a first rectifier circuit and a second rectifier circuit respectively coupled to a first end and a second end of the first secondary winding;
and a second secondary side circuit including a third rectifier circuit and a fourth rectifier circuit respectively coupled to a first end and a second end of the second secondary winding.

16. The power converter of claim 15, wherein the primary side circuit includes full bridge circuit, and the first and second transistors are part of the full bridge circuit.

17. The power converter of claim 15, wherein the first secondary side circuit includes a full bridge circuit, and the first and second rectifier circuits are part of the full bridge circuit.

18. The power converter of claim 15, wherein:
the core is a first core;
the power converter includes:
a second core in the substrate, and the primary winding wraps around the first and second cores;
a third secondary side circuit on the substrate; and
a third secondary winding in the second or third metal layers of the substrate, the third secondary winding wrapping around the second core and coupled to the third secondary side circuit on the substrate.

19. The power converter of claim 15, wherein the substrate has opposite first and second surfaces; and the primary side circuit and the first secondary side circuit are on the first surface, and the second secondary side circuit is on the second surface.

20. A system comprising:
a processor;
a multiphase converter coupled to the processor, the multiphase converter including:
a substrate including first, second, and third metal layers;
a core in the substrate;
a primary winding in the first metal layer of the substrate, the primary winding wrapping around the core;
a first secondary winding in the second metal layer of the substrate, the first secondary winding wrapping around the core; and
a second secondary winding in the third metal layer of the substrate, the second secondary winding wrapping around the core;
a primary side circuit including a first transistor and a second transistor respectively coupled to a first end and a second end of the primary winding;
a first secondary side circuit including a first rectifier circuit and a second rectifier circuit respectively coupled to a first end and a second end of the first secondary winding; and
a second secondary side circuit including a third rectifier circuit and a fourth rectifier circuit respectively coupled to a first end and a second end of the second secondary winding.

21. The system of claim 20, wherein:
the core is a first core;
the multiphase converter includes:
a second core in the substrate, and the primary winding wraps around the first and second cores;
a third secondary side circuit on the substrate;
a third secondary winding in the second or third metal layers of the substrate, the third secondary winding wrapping around the second core and coupled to the third secondary side circuit on the substrate; and
a third secondary side circuit including a fifth rectifier circuit and a sixth rectifier circuit respectively coupled to a first end and a second end of the third secondary winding.
